(19) United States
(12) Patent Application Publication
(10) Pub. No.: US 2026/0164751 A1
(43) Pub. Date: Jun. 11, 2026

(54) GROUP III-N DEVICE INCLUDING CONTACTS WITH MULTIPLE CONDUCTIVE COLUMNS

(71) Applicant: TEXAS INSTRUMENTS INCORPORATED, Dallas, TX (US)

(72) Inventors: Dong Seup Lee, Allen, TX (US); Takayuki Enda, Aizuwakamatsu-shi (JP); Kevin Lee, Allen, TX (US); Jungwoo Joh, Allen, TX (US)

(21) Appl. No.: 18/973,731

(22) Filed: Dec. 9, 2024

(51) Int. Cl. H10D 64/23; H01L 21/285; H10D 30/01; H10D 30/47; H10D 64/01; H10D 64/66

(52) U.S. Cl. CPC H10D 64/257; H10D 30/015; H10D 30/475; H10D 64/01; H10D 64/0125; H10D 64/256; H10D 64/668

(57) ABSTRACT

Semiconductor devices including contacts with multiple conductive columns are described. In one example, a semiconductor device comprises a semiconductor substrate including a source region, a gate region, a drain region, and a drain access region, where a III-N heterojunction structure is disposed over the semiconductor substrate. The III-N heterojunction structure includes a buffer layer over the semiconductor substrate and a barrier layer over the buffer layer. A contact is disposed in at least one of the source region and a drain region, where the contact includes multiple conductive columns coupled to the III-N heterojunction structure.

### FIELD OF THE DISCLOSURE

Disclosed implementations relate generally to the field of group III-N semiconductor devices and their fabrication.

### BACKGROUND

Group III nitride materials (also referred to as III-N materials) possess a unique combination of physical and electrical properties found to be beneficial in modern microelectronics and optoelectronics. Among these properties are wide bandgap, high saturated drift velocity and breakdown voltage, high thermal conductivity, robust chemical and thermal stability, etc. Due to these characteristics, III-N materials are being considered as promising materials for fabrication of powerful high-frequency transistors capable of functioning at high temperatures and in hostile environments. Whereas advances in III-N devices and their fabrication continue to grow apace, several lacunae remain, thereby requiring further innovation as will be set forth hereinbelow.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a semiconductor device comprises a semiconductor substrate including a source region, a gate region, a drain region, and a drain access region between the gate region and the drain region, where a III-N heterojunction structure is disposed over the semiconductor substrate. The III-N heterojunction structure includes a buffer layer over the semiconductor substrate and a barrier layer over the buffer layer. A contact is disposed in at least one of the source region and a drain region, where the contact includes multiple conductive columns coupled to the III-N heterojunction structure.

In one example, a method of fabricating a semiconductor device is disclosed. The method comprises, among others, forming a III-N heterojunction structure over a semiconductor substrate including a source region, a gate region, a drain region, and a drain access region between the gate region and the drain region, the III-N heterojunction structure including a buffer layer over the semiconductor substrate and a barrier layer over the buffer layer; and forming a contact in at least one of the source region and the drain region, the contact including multiple conductive columns coupled to the III-N heterojunction structure.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure are described in the following Detailed Description taken in connection with the appended claims and with reference to the attached drawing Figures in which:

FIG. 1A depicts a layout of a semiconductor device including contacts with multiple conductive columns according to some examples of the present disclosure;

FIGS. 1B-1 to 1B-3 depict cross-sectional views of a contact of a semiconductor device according to some examples;

FIG. 2A to 2H-2 depict layouts of multi-column contacts that may be employed for source and/or drain electrodes of a semiconductor device according to some examples;

FIGS. 3A to 3I-3 depict cross-sectional views of a semiconductor device including a GaN device at various stages of a process flow according to an example of the present disclosure;

FIG. 4 depicts a cross-sectional view of a semiconductor device including a GaN device according to another example of the present disclosure;

FIGS. 5A and 5B are flowcharts of methods of fabricating a semiconductor device including contacts with multiple conductive columns according to some examples of the present disclosure; and

FIG. 6 depicts an example GaN resistor including multi-column contacts according to an example of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of improving performance characteristics of semiconductor devices based on Group III nitride materials, also referred to as III-N materials, such as gallium nitride (GaN) devices.

GaN devices, e.g., GaN transistors, provide certain performance advantages over silicon, including lower on-state resistance (e.g., drain-source resistance or R_{DSON}), lower switching losses, and improved breakdown voltage, among others. GaN transistors include a hetero epitaxy structure with a junction between materials of different bandgaps (e.g., a heterojunction structure), such as aluminum gallium nitride (AlGaN) and gallium nitride, to provide a 2-dimensional electron gas (2 DEG) formed within the AlGaN/GaN hetero epitaxy structure that is used for device operation—e.g., forming a channel of the GaN device. The 2-dimensional electron gas (2 DEG) may be referred to as a 2 DEG channel. Depletion mode (DMODE) GaN transistors are normally on, whereas enhancement mode (EMODE) GaN transistors are normally off. In some examples, EMODE GaN transistors include a gate stack with a p-type doped gallium nitride (p-GaN) layer that depletes the 2 DEG beneath the gate stack at zero or negative gate bias. In some examples, the p-GaN layer may comprise a GaN layer doped with magnesium (Mg) or other p-type dopants. Applying a positive gate voltage enhances the 2 DEG under the gate and turns the EMODE GaN device on to allow current flow between the source and drain.

One of the issues affecting the performance of semiconductor devices including GaN devices relates to contact resistance. As the contact resistance of a device, e.g., including source and drain contact resistances, continues to become a significant component of a device's total resistance, especially as linewidths continue to shrink, efforts are being undertaken to reduce the contact resistance so as to lower power losses in the device as well as to improve switching performance of the device. Whereas the fabrication of source/drain contacts in a device may include high temperature annealing processes (e.g., at temperatures greater than 750° C.) in order to facilitate formation of contacts with desirable electrical properties, such thermal processes can give rise to various deleterious effects, especially in GaN devices where surface passivation layers may be provided in some implementations.

For example, a GaN device may be formed with one or more GaN layers over a suitable semiconductor substrate, e.g., including a silicon substrate, where the GaN layers may form a heterojunction structure (e.g., III-N heterojunction structure) over the semiconductor substrate. To address detrimental effects of charge trapping, such as current collapse, increased dynamic on-resistance, etc., one or more surface passivation layers may be provided over the heterojunction structure. Further, one or more field plate (FP) structures may be provided in some examples to mitigate the effects of concentrated electric fields in a GaN device, e.g., at the edges of a gate electrode of the device. Where FP structures and/or surface passivation layers are implemented, dielectric films having a high dielectric constant (high κ), e.g., silicon nitride (SiN) films having κ values ranging from around 7 to around 10, may be provided in order to suppress charge traps and/or reduce susceptibility to high electric fields.

SiN layers used for providing dielectric separation for FP structures and/or for passivating surface states in GaN devices may constitute material compositions that include hydrogen. During high temperature processes, e.g., annealing processes at temperatures greater than 750° C. used in device contact formation, hydrogen may diffuse into the p-GaN layer of a GaN device, where the diffused hydrogen may react with the dopants, e.g., Mg, and form a deactivated dopant complex that reduces the effect of the dopants in the operation of the device. Accordingly, the diffused hydrogen in the p-GaN layer may cause deterioration of the device's electrical characteristics such as reduced threshold voltage (Vₜₕ) and transconductance (gₘ), increased punch-through leakage, etc.

Furthermore, charge trapping near the contact of a device (e.g., a drain contact) can be significant under high voltage/current stress in some arrangements, which can negatively impact device reliability (e.g., R_{DSON} stability) in some implementations.

Examples of the present disclosure recognize the foregoing challenges and provide contact designs that not only facilitate lower contact resistance but also advantageously reduce the risk of p-dopant inactivation in certain GaN transistors. In some arrangements, multiple conductive columns may be formed as part of a source/drain contact structure that may increase a total perimeter area in contact with the III-N heterojunction structure—e.g., a channel of a GaN transistor which includes a 2D electron gas (2 DEG) or a 2D hole gas (2DHG). In this manner, the overall contact resistance may be decreased (lowered) due to the increased perimeter contact area according to some examples. Further, a silicon liner may be provided in the formation of conductive columns to facilitate a lower temperature contact annealing process, e.g., at temperatures less than around 700° C. in some arrangements. Accordingly, diffusion of hydrogen from high κ dielectric layers (e.g., SiN layers) into a p-GaN layer of the device is reduced or suppressed, thus mitigating the risk of dopant inactivation in the p-GaN layer.

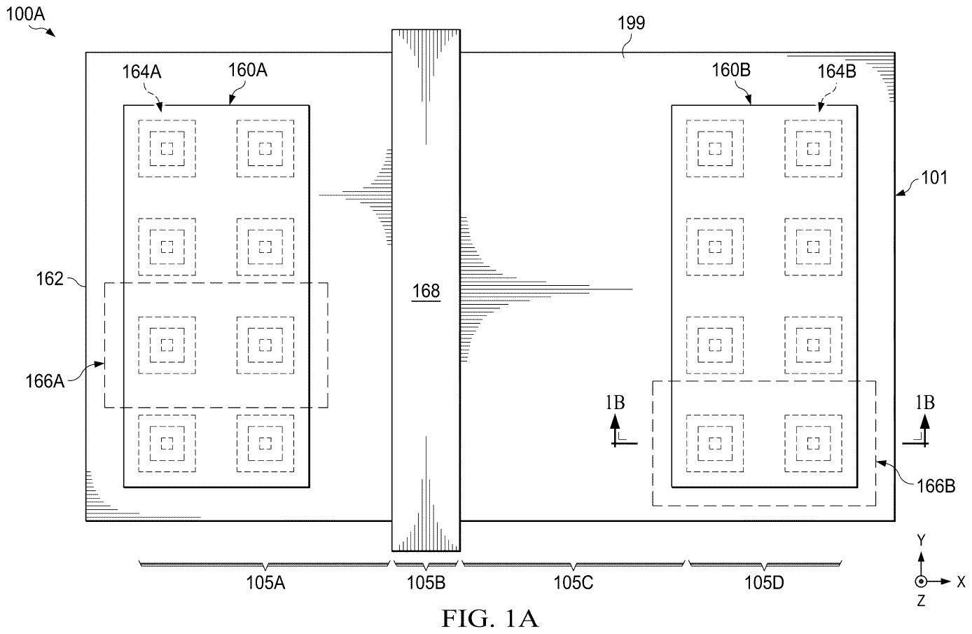

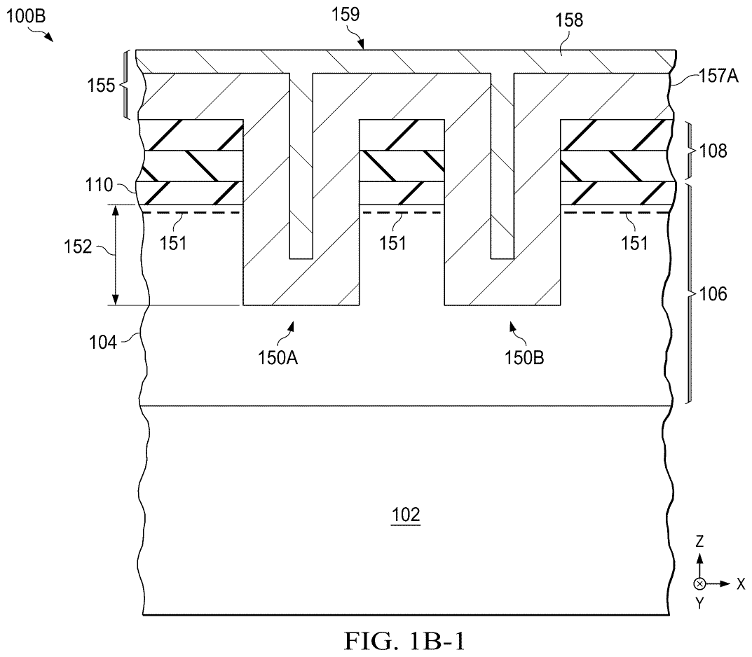

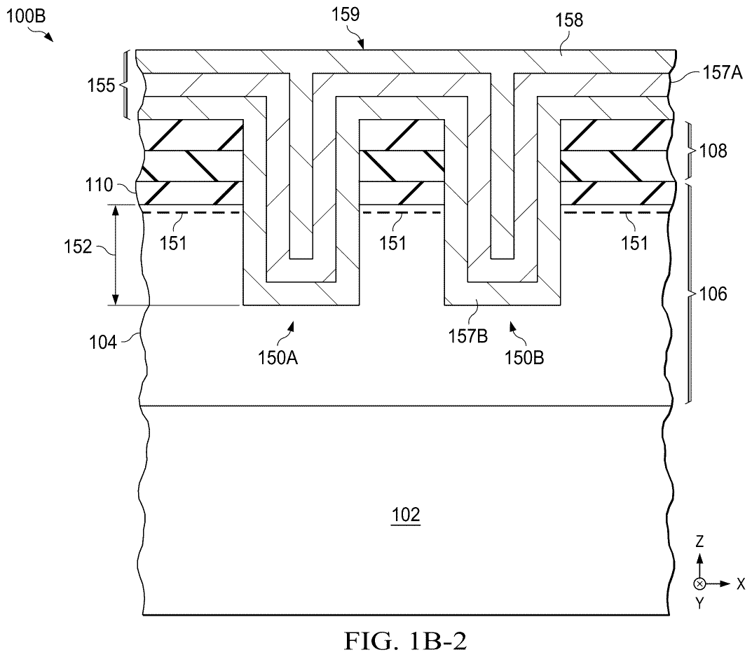

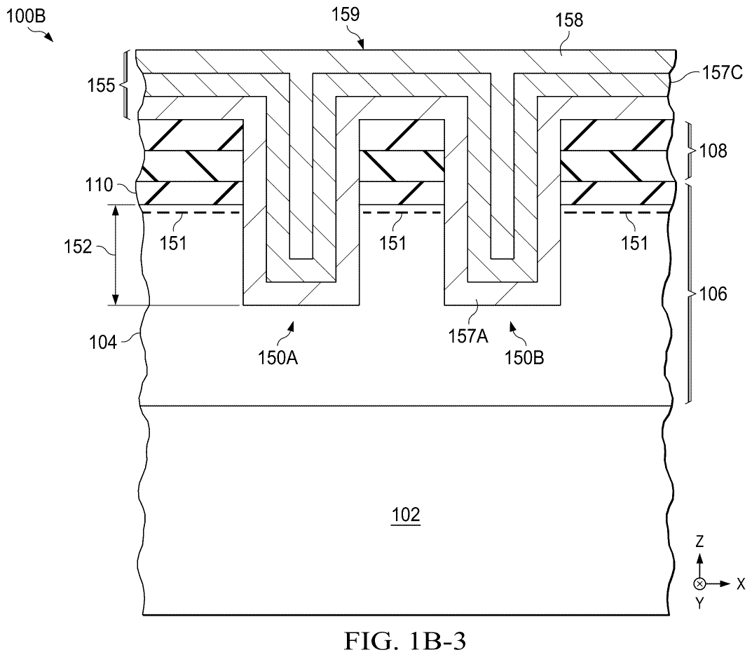

In some further examples, devices having contacts with multiple conductive columns may have better reliability (e.g., R_{DSON} stability) under high voltage/current conditions, which may be attributed to the multiple conductive column design of the contact. For example, a first set of conductive columns of a drain contact may be located closer to a gate stack of the GaN transistor than a second set of conductive columns of the drain contact such that the first set of conductive columns may protect (e.g., shield) the second set of conducive columns from charge trapping events proximate to the drain contact. In other words, because of the corrugated nature of the contact perimeter area as described with reference to FIGS. 1B-1 to 1B-3, certain portions of the contact perimeter area (e.g., the interior perimeter area of conductive columns) may be shielded from charge trapping events. Whereas the examples herein may provide various structures, materials and processes that may engender these and other beneficial effects, no particular result is a requirement unless explicitly recited in a particular claim.

Referring to the drawings, FIG. 1A depicts a layout of a semiconductor device 100A including a contact design where one or more contacts each having multiple conductive columns may be provided for obtaining reduced contact resistance according to some examples. As illustrated, the semiconductor device 100A includes a GaN device 101 having an area 199 (e.g., an active area, a device area, etc.) defined by an isolation boundary 162 formed by a suitable isolation process. The area 199 includes a source region 105A (which may also include a source access region as will be set forth further below), a gate region 105B, a drain region 105D and a drain access region 105C disposed between the gate region 105B and the drain region 105D, where a gate layer 168 may be provided in the gate region 105B.

By way of example, the GaN device 101 may include source/drain contacts 160A, 160B each including a plurality of conductive columns that may be organized as arrays or other configurations in the source and drain regions 105A, 105D, respectively. In some implementations, conductive columns provided for forming a source contact (e.g., source contact 160A) may be organized or arranged in a different configuration than the conductive columns provided for forming a drain contact (e.g., drain contact 160B). For purposes of examples herein, unless otherwise stated, the terms “column” or “contact column” in the context of a multi-column contact design refer to a vertical conductive column comprising a multi-layer stack that is aligned along a surface normal (e.g., parallel to the Z-axis) of the heterojunction structure of a GaN device such as the GaN device 101. In some other contexts, however, the term “column” may refer to a group of entities provided as part of an array of entities organized in an [N×M] matrix configuration disposed along or on a horizontal surface, where N refers to the number of rows and M refers to the number of columns of the matrix configuration.

The source contact 160A includes a first plurality of conductive columns 164A and the drain contact 160B includes a second plurality of conductive columns 164B. The conductive columns 164A, 164B may be configured to vertically extend (e.g., along the Z-axis orthogonal to the X-Y plane) and couple to at least a portion of a heterojunction structure (not explicitly shown in FIG. 1A) of the GaN device 101 for forming multi-column source and drain contacts 160A, 160B in the source region 105A and the drain region 105D, respectively. Depending on implementation, each plurality of conductive columns 164A and 164B may be spatially organized or arranged relative to a surface of the heterojunction structure (e.g., parallel to the X-Y plane) in various configurations, e.g., including array configurations with N rows and M columns in some examples.

As depicted, the first plurality of conductive columns 164A organized as a first array (e.g., including N₁ rows and M₁ columns where N₁ is 4 and M₁ is 2 in this particular example) is provided for forming and/or operating as a multi-column source contact 160A in the source region 105A. In similar fashion, the second plurality of conductive columns 164B organized as a second array (e.g., including N₂ rows and M₂ columns where N₂ is 4 and M₂ is 2 in this particular example) is provided for forming and/or operating as a multi-column drain contact 160B in the drain region 105D.

Depending on implementation, each column of the conductive columns 164A, 164B may include a metal silicide formed from a silicon-metal (Si-Met or Si-metal) stack in a multi-layer fabrication process including a low temperature plasma enhanced chemical vapor deposition (PECVD) Si deposition process. The silicon layer may facilitate forming ohmic contact with the heterojunction structure—e.g., a buffer layer including a channel of the GaN device 101 (e.g., 2 DEG or 2DHG) according to some examples as will be described in detail below. Further, in some versions of the examples where a p-GaN layer is provided as part of the GaN device 101, the multi-column contact design of FIG. 1A comprising the conductive columns 164A and the conductive columns 164B may be operable to mitigate dopant deactivation of the p-GaN layer of the GaN device 101 in additional and/or alternative arrangements.

FIGS. 1B-1 to 1B-3 depict cross-sectional views of a multi-column contact 100B of a semiconductor device where conductive columns may be formed as Si-metal stacks or columns in an active area of the semiconductor device according to some examples. In some arrangements, the multi-column contact 100B shown in FIGS. 1B-1 to 1B-3 is representative of a row of conductive columns (e.g., row 166A) formed as part of the first plurality of conductive columns 164A and arranged as a [4×2] array in the source region 105A as shown in FIG. 1A. Likewise, in some arrangements, the multi-column contact 100B is representative of a row of conductive columns (e.g., row 166B) of the second plurality of conductive columns 164B also arranged as a [4×2] array in the drain region 105D shown in FIG. 1A.

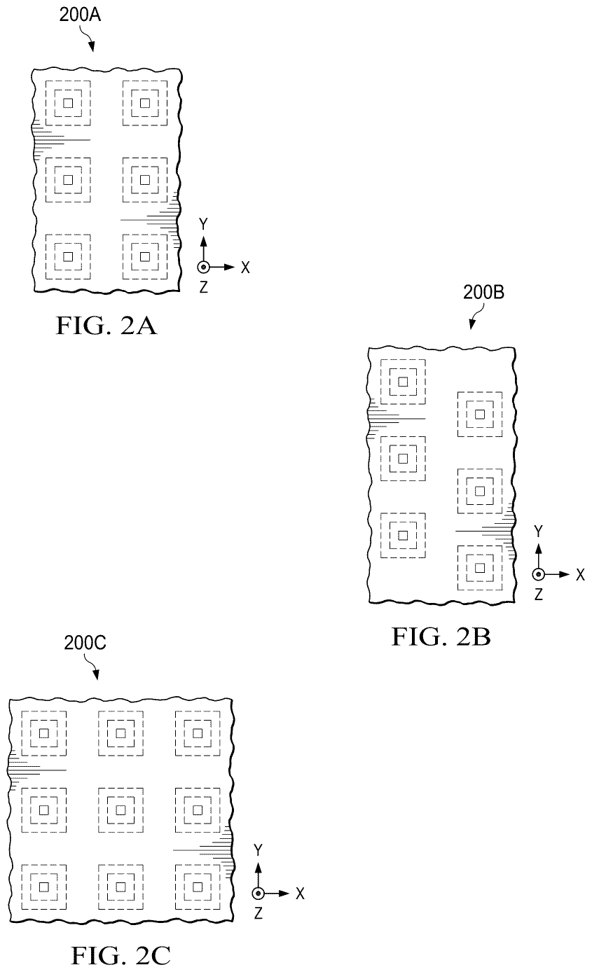

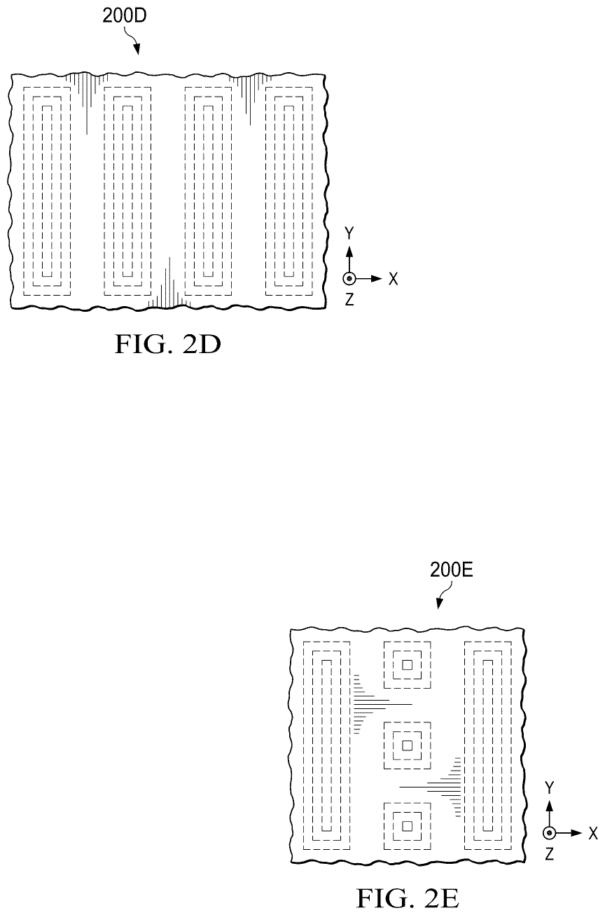

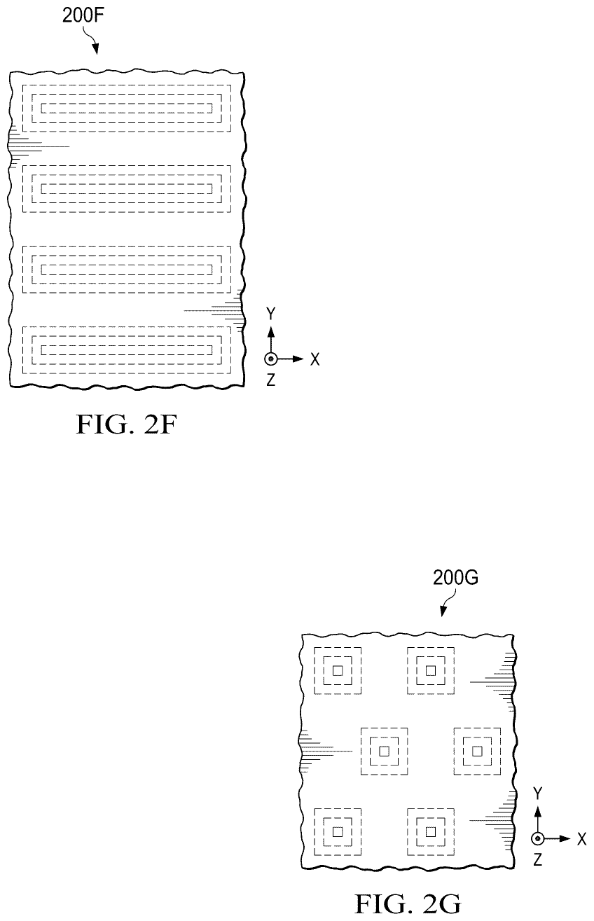

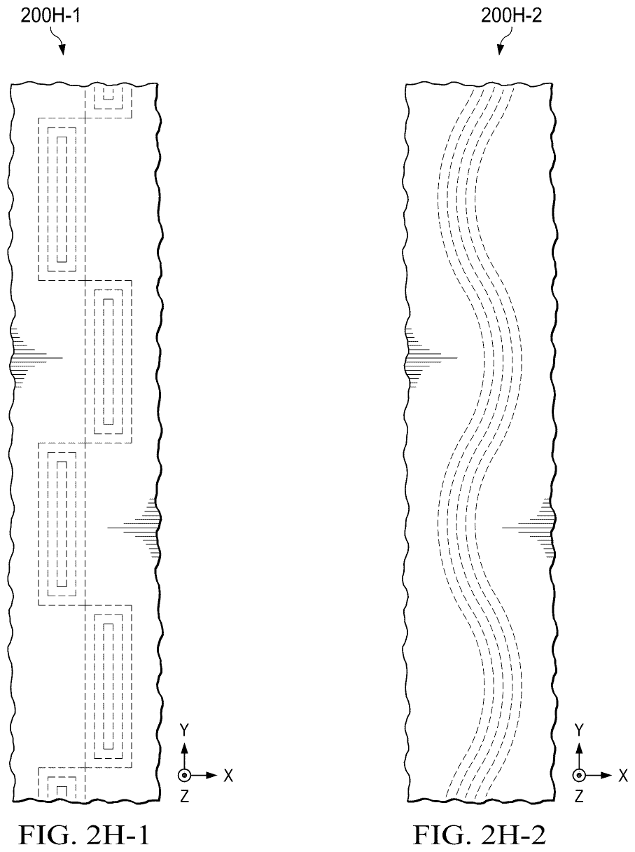

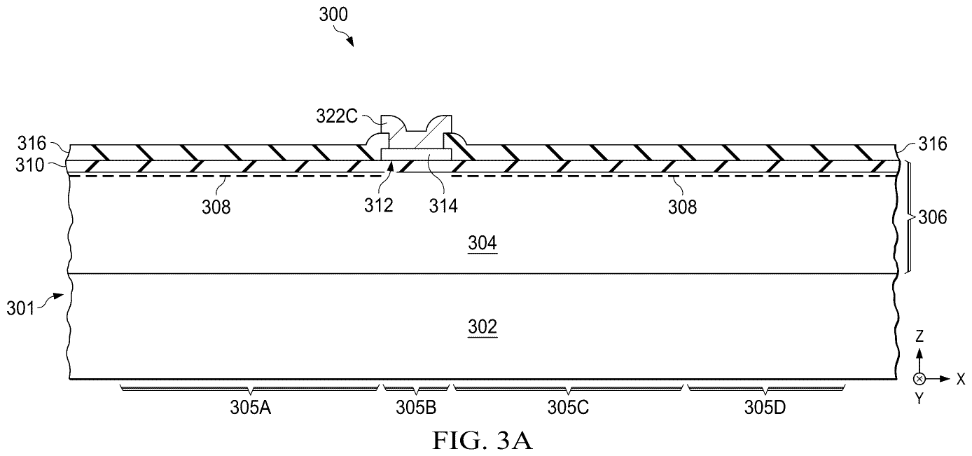

The examples depicted in FIGS. 1B-1 to 1B-3 illustrate three variations of the multi-column contact 100B formed after an annealing process (e.g., a silicide-forming thermal process) is performed as part of contact metallization. According to the examples herein, a metal silicide may be formed based on a silicon layer and a refractory metal layer of a multi-layer stack where the silicon and the refractory metal may be combined or consumed in varying degrees. As will be set forth below, the multi-layer stack may be formed in a process that includes forming the silicon layer, forming the refractory metal layer over the silicon layer and forming a conductive layer over the refractory layer. In one scenario, as illustrated in FIG. 1B-1, entire silicon and refractory metal of the multi-layer stack may be combined in the annealing process to form a metal silicide. In another scenario, as illustrated in FIG. 1B-2, not all of the silicon layer is reacted (e.g., converted or consumed) in forming the metal silicide. Accordingly, an unconsumed portion of the silicon layer may remain under the metal silicide. In yet another scenario, as illustrated in FIG. 1B-3, not all of the refractory metal layer is reacted (e.g., converted or consumed) in forming the metal silicide, thus leading to a configuration where an unconsumed portion of the refractory metal layer may remain above the metal silicide. In each of the foregoing scenarios, the thicknesses of the metal silicide, any remaining portions of the unreacted silicon and/or refractory metal layers in a conductive column may depend on respective initial thicknesses of the silicon and refractory metal layers as well as the processing conditions of an annealing process.

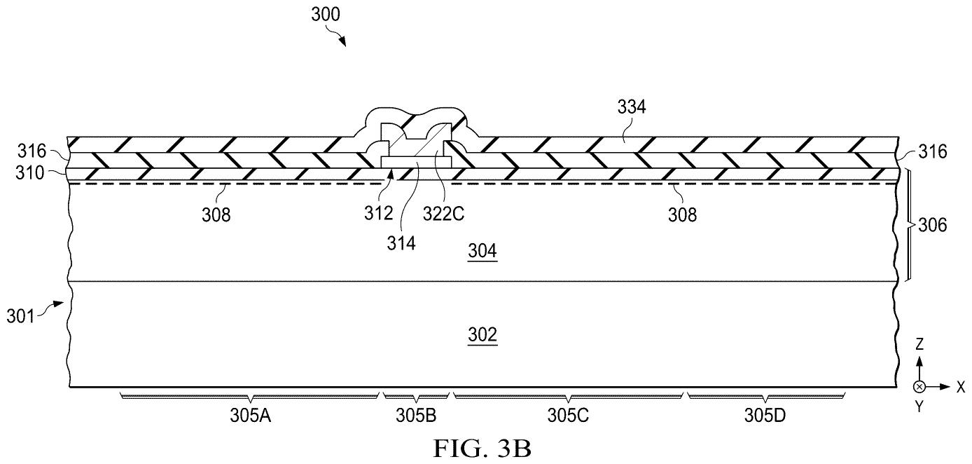

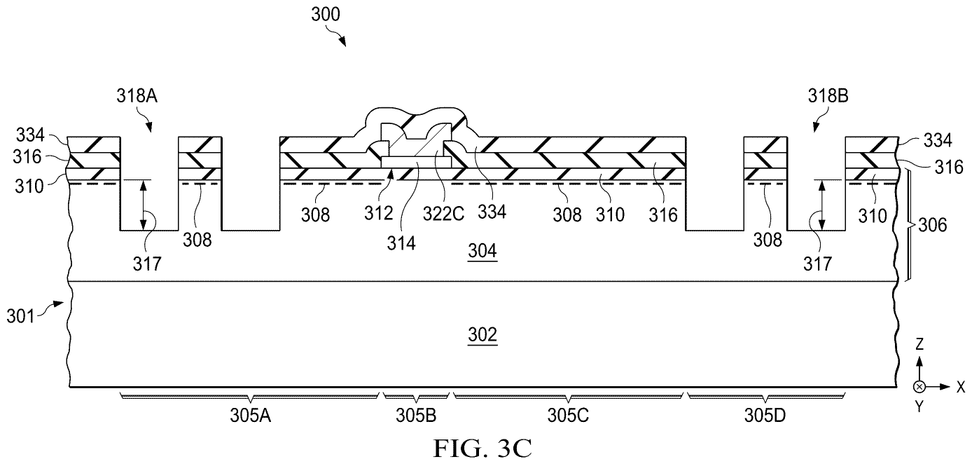

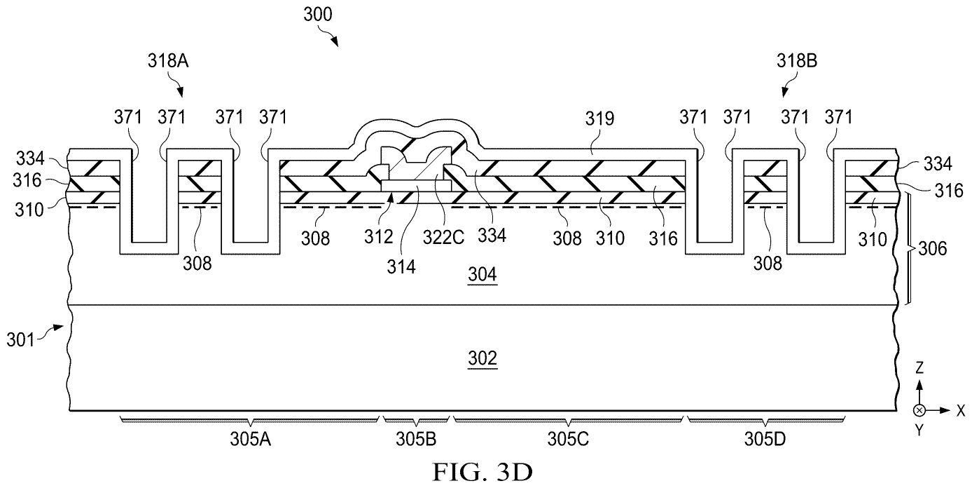

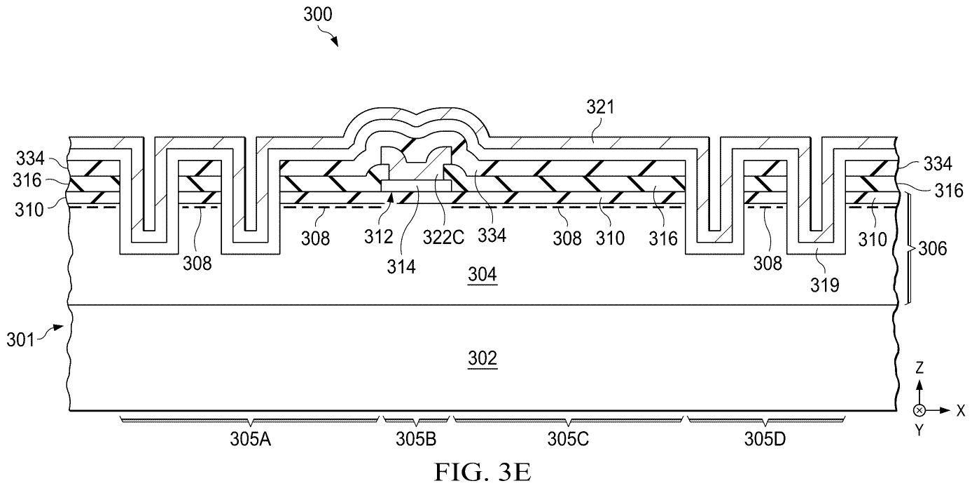

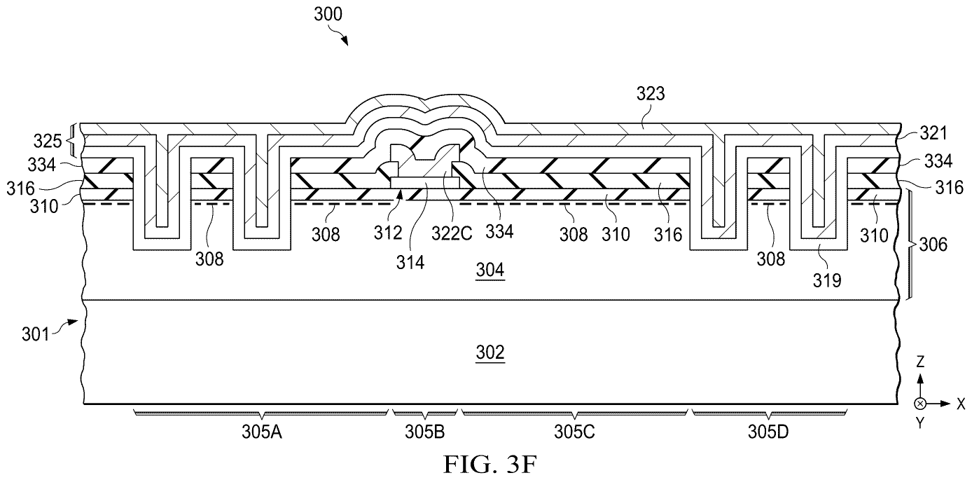

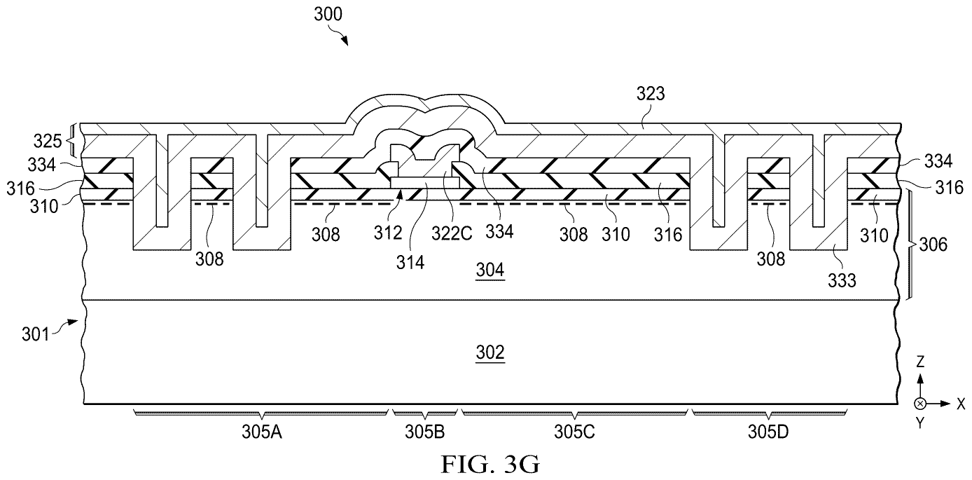

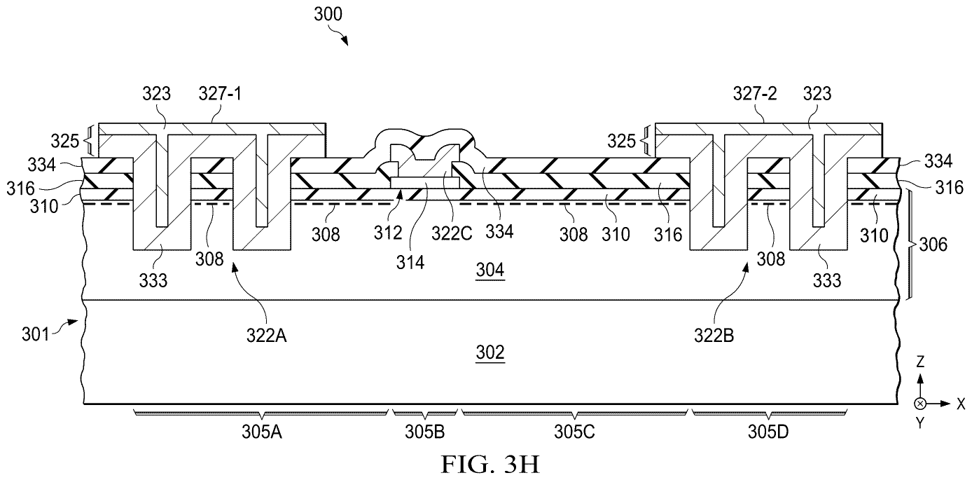

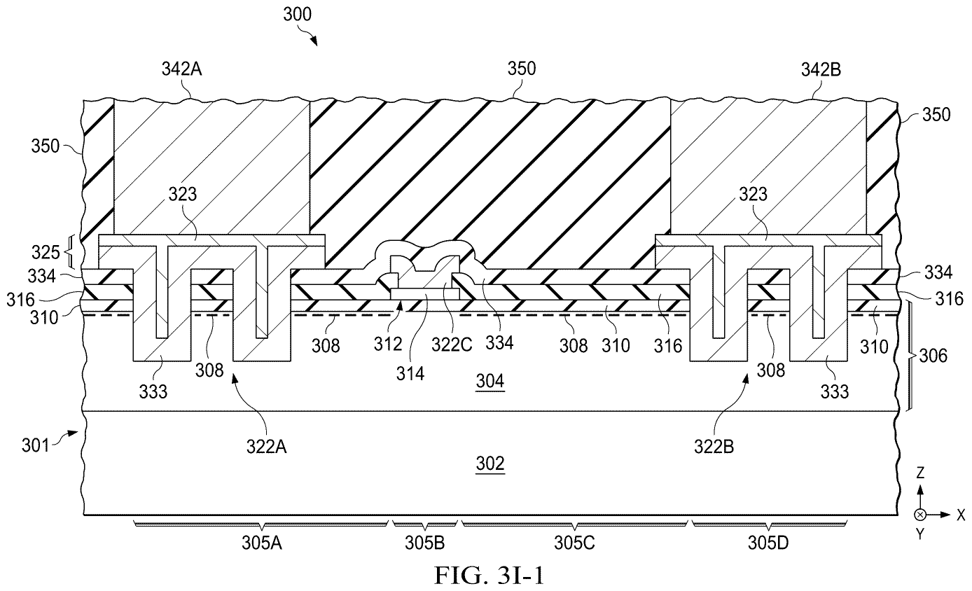

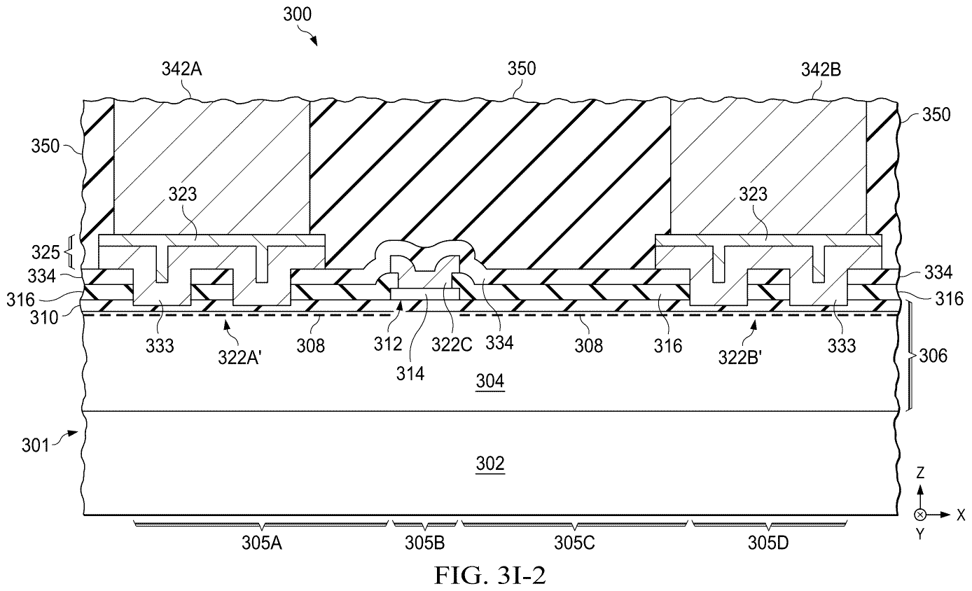

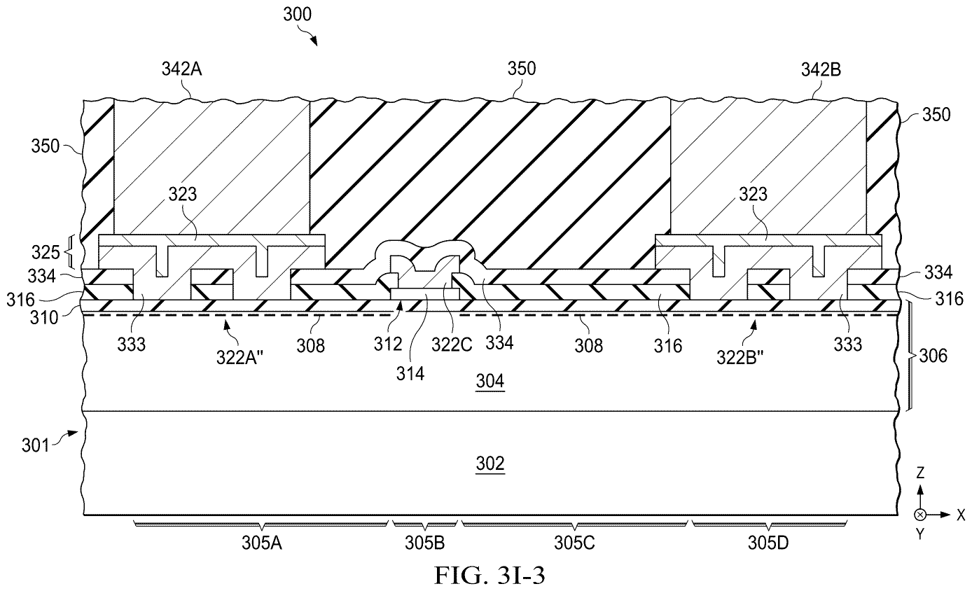

A description of the multi-column contact 100B is set forth below in detail with reference to the example of FIG. 1B-1. The description of the multi-column contact 100B of FIG. 1B-1 is also applicable to the examples depicted in FIGS. 1B-2 and 1B-3 except for the variations in the metal silicide configurations according to the various scenarios set forth above. A III-N heterojunction structure 106 comprising a barrier layer 110 over a buffer layer 104 is disposed over a semiconductor substrate 102 as will be described in additional detail further below in reference to an example process flow depicted in FIGS. 3A to 3I-3. A dielectric stack 108 comprising one or more layers and/or sublayers is disposed over the III-N heterojunction structure 106, where the material composition(s) and/or thickness(es) of the dielectric layers/sublayers of the stack 108 may vary depending on implementation. A channel 151, e.g., a 2 DEG, may be provided proximate to an interface between the barrier layer 110 and the buffer layer 104 for facilitating device operation according to EMODE or DMODE device functionality.

As illustrated, the multi-column contact 100B comprises two conductive columns 150A, 150B that may be formed by a contact formation process including Si deposition and metal stack formation following the formation of contact apertures corresponding to the conductive columns 150A, 150B, as will described below. In some arrangements, the conductive columns 150A, 150B may couple to at least a portion of the III-N heterojunction structure 106 for making electrical contact. In some arrangements, the conductive columns 150A, 150B extend into the buffer layer 104 by a distance 152 although it is not a requirement. Each conductive column 150A, 150B includes a metal silicide layer 157A (or, a metal silicide, for short) formed from a Si layer and a refractory metal layer (not specifically shown in FIG. 1B-1), where the metal silicide layer 157A may have sidewalls that contact the buffer layer 104, e.g., including the 2 DEG channel 151. A conductive layer 158, e.g., comprising aluminum, is disposed over the metal silicide 157A, forming a multi-layer metal stack 155. A contact pad 159 of the multi-column contact 100B is formed by patterning the multi-layer stack 155. In some arrangements, the metal stack 155 may also include a barrier layer comprising a refractory metal (not specifically shown in FIGS. 1B-1 to 1B-3) formed over the conductive layer 158. Depending on implementation, the conductive columns 150A, 150B may each have a respective cross-sectional area in the X-Y plane, e.g., parallel to a horizontal surface of the III-N heterojunction structure 106, where the cross-sectional areas may be the same or different and may have a variety of shapes and sizes.

As illustrated in FIG. 1B-1, providing multiple conductive columns, e.g., conductive columns 150A, 150B, in a contact design creates more sidewalls than would have been available in a single conductive column for contacting the III-N heterojunction structure. The additional sidewalls of the multiple conductive columns 150A, 150B may therefore constitute a corrugated perimeter area extending in both X- and Y-directions. Accordingly, a total perimeter area in contact with at least a portion of the III-N heterojunction structure, e.g., the buffer layer 104 including the 2 DEG channel 151, may be increased in the examples herein. In this manner, the overall contact resistance of the multi-column contact 100B may be decreased (lowered) due to the increased perimeter contact area according to the teachings of the present disclosure.

Further, increased perimeter contact area of a multi-contact design in combination with providing a silicon layer in forming conductive columns may advantageously allow an annealing process to be performed at lower temperatures while still achieving desired contact resistance. Additionally, lower temperatures used in annealing are expected to mitigate the risk of p-GaN deactivation in some examples as will be set forth further below.

FIG. 1B-2 depicts an example variation of the multi-column contact 100B where a remaining silicon layer 157B representing an unconsumed portion of a silicon layer is shown. As depicted, the remaining silicon layer 157B underlies the metal silicide 157A and may have a thickness less than an initial thickness of the silicon layer as previously noted.

FIG. 1B-3 depicts an example variation of the multi-column contact 100B where a remaining refractory metal layer 157C representing an unconsumed portion of a refractory metal layer is shown. As depicted, the remaining refractory metal layer 157C extends over or above the metal silicide 157A and may have a thickness less than an initial thickness of the refractory metal layer as previously noted.

Although the semiconductor device 100A of FIG. 1A is shown with conductive columns 164A and 164B having same cross-sectional areas, shapes, and/or being organized in identical or similar array configurations, etc., such features are not limitations. Additional and/or alternative examples herein may therefore include a multi-column contact design where the conductive columns for a source contact and/or a drain contact may have different cross-sectional areas, shapes and spatial configurations depending on implementation. Further, a multi-column source contact design of a GaN device may not be identical to a multi-column drain contact design of the GaN device in some examples. In general, conductive columns of a multi-column source/drain contact design may be fabricated in a variety of shapes having different cross-sectional areas and/or configurations in a customizable manner as long as applicable critical dimension (CD) design rules are not violated and process corners are not compromised.

FIG. 2A to 2H-2 depict layouts of various multi-column contact designs that may be employed for fabricating source/drain contacts (also referred to as source/drain electrodes) of a semiconductor device according to some examples herein. In some implementations, conductive columns may be arranged as regular array configurations such as rectangular or square arrays, e.g., design 200A and design 200C depicted in FIGS. 2A and 2C, respectively. In some implementations, a multi-column contact design may include staggered columns of conductive columns, e.g., design 200B shown in FIG. 2B, where each column may include a plurality of conductive columns. In some arrangements, a multi-column contact design may comprise a “continuous column” design 200D shown in FIG. 2D, where there is no segmentation of a conductive column along a planar axis (e.g., the X-axis) of the layout, thus resulting in a plurality of elongated conductive cuboids aligned along the Y-axis. In similar fashion, a multi-column contact design may comprise a design 200F where there is no segmentation of a conductive column along the Y-axis of the layout, yielding a “continuous row” design 200F shown in FIG. 2F, which may include a plurality of elongated conductive cuboids aligned along the X-axis. A combinational multi-column contact design 200E including continuous conductive columns and segmented conductive columns may be provided in some arrangements as shown in FIG. 2E. A checkered multi-column contact design 200G may be provided in some arrangements as shown in FIG. 2G. FIG. 2H-1 depicts another staggered column design 200H-1 where two columns of conductive columns may be laid out such that the staggered conductive columns are in contact with each other.

Whereas FIGS. 2A to 2H-1 depict intended patterning of multiple conductive columns of a contact design in a layout and corresponding mask set, actual shapes of a pattern in a GaN device may vary slightly from the layout patterns shown in FIGS. 2A to 2H-1 because of inherent morphological differences caused by processing conditions. For example, apertures having a square shape in a layout may be formed more like circular apertures. Likewise, patterns having sharp corners may be formed as features with rounded corners. Further, where a staggered column design is intended (e.g., design 200H-1 shown in FIG. 2H-1), the corresponding feature in a final device structure may have a serpentine form 200H-2 as shown in FIG. 2H-2. Depending on how closely the individual conductive columns are placed in the staggered layout of the design 200H-1, the corresponding serpentine form 200H-2 may have a varying width, e.g., parallel to the X-axis. Accordingly, the scope of the examples set forth herein is intended to include all such process-related morphological variations with respect to a multi-column contact design of the present disclosure.

Turning to FIGS. 3A to 3I-3, depicted therein are cross-sectional views of a semiconductor device including a GaN device with multi-column contacts at various stages of a process flow according to an example of the present disclosure. FIG. 3A depicts an intermediate stage of the semiconductor device 300 formed on a portion of a semiconductor substrate 302, which is analogous to the semiconductor substrate 102 of FIG. 1B in some arrangements. Depending on implementation, the semiconductor substrate 302 may be provided as a silicon wafer, a silicon-on-sapphire wafer, or a silicon carbide wafer, and/or as a semiconductor substrate including cores configured for matching coefficient of thermal expansion (CTE), and/or the like. A buffer layer 304, analogous to the buffer layer 104 of FIG. 1B, is formed on the substrate 302 and may comprise one or more layers of III-N semiconductor material. In some examples where the substrate 302 is implemented as a silicon wafer or a sapphire wafer, the buffer layer 304 may include a nucleation layer having a stoichiometry that includes aluminum to match a lattice constant of the substrate 302. In some examples, the buffer layer 304 may further include layers/sublayers of aluminum gallium nitride (AlGaN) with decreasing aluminum content, including an unintentionally doped (UID) GaN sublayer in some arrangements. For purposes of the examples herein, the various layers/sublayers of a buffer layer, e.g., the buffer layer 304, are not specifically shown in the Figures of the present disclosure.

Depending on implementation, the buffer layer 304 may have a thickness of about 1 micron (μm) to several microns, e.g., 3.5 μm to 7.0 μm, which may be formed by a suitable epitaxial process, e.g., a metal organic vapor phase epitaxy (MOVPE) process (also known as organometallic vapor phase epitaxy (OMVPE) or metalorganic chemical vapor deposition (MOCVD)), where several sequential steps may be performed to form the various constituent layers and/or sublayers. In some arrangements, an example buffer layer 304 may therefore comprise a stack of multiple layers/sublayers of suitable materials and compositions (e.g., GaN, AlGaN, etc.) as noted above, where the layers/sublayers may have variable thicknesses depending on the technology and device application. In some arrangements, the buffer layer 304 may include AlGaN-based transition layers, epitaxial layers with strain-layer superlattice (SLS) structures, and the like.

The buffer layer 304 may be formed over an area of the substrate 302, where different regions such as a source region 305A, a gate region 305B, a drain region 305D and a drain access region 305C between the gate region 305B and the drain region 305D may be provided with respect to a GaN device 301. The source region 305A may be regarded as including a source access region (not specifically shown in the Figures), which may refer to a region between a multi-column source electrode or contact (e.g., source electrode 322A as shown in FIG. 3G) and the gate region 305B similar to the drain access region 305C. A channel layer may be provided as part of the buffer layer 304—e.g., a top portion of the buffer layer 304 proximate to a barrier layer 310. Whereas a channel layer may primarily include GaN material, there may be optional trace amounts of other group III elements, such as aluminum or indium, in some implementations.

A barrier layer 310 comprising III-N semiconductor material is formed over the buffer layer 304 in a suitable epitaxy process. In an example arrangement, the barrier layer 310 may have a thickness ranging from about 1 nanometer (nm) to about 60 nm, and may include aluminum and nitrogen. In some versions of this example, the barrier layer 310 may include gallium at a lower atomic percent than aluminum. In some versions, the barrier layer 310 may also include indium. In some examples, the barrier layer 310 includes an AlGaN layer.

The barrier layer 310 over the buffer layer 304 is operable as part of a heterojunction structure 306 for causing the formation of a 2 DEG (e.g., 2 DEG 308 shown in FIGS. 3B-3H) proximate to an interface between the barrier layer 310 and the buffer layer 304. In some examples, the stoichiometry and thickness of the barrier layer 310 may be configured to provide a suitable free charge carrier density (e.g., 3×10¹² cm⁻² to 2×10¹³ cm⁻²) of the 2 DEG for facilitating the device operation.

For purposes of effectuating EMODE functionality, a p-doped III-N layer 314, e.g., comprising one or more layers of III-N material, is patterned over the barrier layer 310 in the gate region 305B as shown in FIG. 3A. In some examples, the p-doped III-N layer 314 may also be referred to as a p-III-N layer or a p-GaN layer. The formation of the p-GaN layer 314 causes the 2 DEG to be reduced—e.g., absent in some cases. In versions of this example, the p-doped III-N layer 314 may comprise a GaN layer doped with magnesium (Mg) or other p-type dopants. In some examples, the p-doped GaN layer 314 may include a p-dopant concentration of about 1×10¹⁷ atoms/cm³ to 1×10²¹ atoms/cm³ and may have a thickness of about 10 nm to 200 nm. Although the semiconductor device 300 depicted in FIGS. 3A to 3I-3 includes EMODE GaN transistor, the present disclosure is not limited thereto. For example, the multi-column contacts (e.g., multi-column contacts depicted in FIGS. 1B-1 to 1B-3) may be used for DMODE GaN transistors.

In some additional and/or alterative arrangements, additional layers such as an AlGaN cap layer of about 4 nm to 10 nm (e.g., devoid of p-doping) and/or a low-pressure chemical vapor deposition (LPCVD) silicon nitride (SiN) cap layer of about 10 nm to 20 nm, which are not specifically shown in the Figures, may be optionally provided over the p-GaN layer 314.

As illustrated, FIG. 3A depicts a stage after patterning the p-GaN layer 314 using a mask and appropriate photolithography and etch process to form a part of a gate stack 312, which may include optional capping layers in some implementations (e.g., AlGaN/SiN cap layers) in addition to a gate electrode or contact 322C formed over the patterned p-GaN layer 314 (and the additional capping layers if present). As a result of patterning the p-GaN layer 314 (e.g., removing portions of the p-GaN layer 314 outside the gate region 305B), the 2 DEG 308 may be established in the channel layer outside the gate region 305B. In some versions of the examples herein, the source region 305A (where a multi-column source electrode or contact is to be formed) and the drain region 305D (where a multi-column drain electrode or contact is to be formed) may be asymmetrically disposed relative to the gate region 305B although it is not a requirement. For example, there may be a greater lateral distance between the gate region 305B and the drain region 305D than a lateral distance between the gate region 305B and the source region 305A by virtue of an access region, e.g., drain access region 305C, disposed between the gate region 305B and the drain region 305D. In some additional and/or alternative arrangements, a source access region may also be provided between the source region 305A and the gate region 305B in a similar manner, as previously noted, while still having source/drain region asymmetry with respect to the gate region 305B.

Although not specifically shown in FIG. 3A, a suitable device isolation step may be implemented to achieve isolation with respect to the GaN device 301. Depending on implementation, an isolation step may include mesa etching, implanting, etc., to define a region where the 2 DEG 308 outside the active area is absent, eliminated or otherwise disrupted. In some examples, an argon implant at 120 keV having a dosage around 5×10¹⁴ atoms/cm² may be implemented to achieve device isolation, although other implant species such as silicon, fluorine, nitrogen, etc., may be used for achieving device isolation in additional and/or alternative examples.

The fabrication stage depicted in FIG. 3A further illustrates a stage after the formation of a gate stack, e.g., gate stack 312, including the gate electrode 322C. In some arrangements, the gate stack 312 may be formed before forming source/drain contacts, e.g., in a gate first flow as set forth in FIGS. 3A-3H, although it is not a requirement. Further, the gate stack 312 may be formed after depositing one or more dielectric layers operable as surface passivation layers in some implementations. By way of example, a dielectric layer 316 comprising a SiN layer having a thickness of about 10 nm to 100 nm may be provided as a surface passivation layer. In an example implementation, the dielectric layer 316, which may be referred to as a first dielectric layer in some examples, may be formed by a high temperature LPCVD process, e.g., at temperatures ranging from about 700° C. to about 850° C., using suitable precursors such as dichlorosilane (DCS) and ammonia (NH₃). Although the dielectric layer 316 is illustrated as a single layer in FIG. 3A, it is not a necessary requirement. Accordingly, the dielectric layer 316 may comprise multiple SiN layers that may be operable as a composite passivation layer in some additional and/or alternative examples. In some arrangements, the first dielectric layer 316 may comprise different materials, e.g., silicon dioxide (SiO₂), silicon oxynitride (SiON), aluminum oxide (Al₂O₃), etc., and may be formed using other techniques such as ALD.

An example gate first flow as illustrated herein includes forming a gate contact aperture (not specifically shown in FIG. 3A) over the p-GaN layer 314 (and any cap layers if present) using a gate contact photolithography and etch process. Subsequently, the gate electrode 322C may be formed in the gate contact aperture from a suitable conductive layer (not specifically shown in FIG. 3A). In some versions, the conductive layer may comprise a metal layer—e.g., formed by sputtering. After depositing the conductive layer, the gate electrode 322C is patterned from the conductive layer based on a suitable gate lithography and etch process. Depending on implementation, the conductive layer from which the gate electrode 322C is formed may comprise one or more metals, such as titanium, nickel, tungsten, platinum, iridium, aluminum, gold, etc., and/or may include other electrically conductive materials such as carbon nanotubes or graphene as well as metallic nitrides such as titanium nitride (TiN), tantalum nitride (TaN) and the like.

FIG. 3B depicts a stage where a dielectric layer 334 is formed over the gate stack 312 and the first dielectric layer 316. In some arrangements, the dielectric layer 334, also referred to as a second dielectric layer, may comprise a SiN layer deposited using a PECVD process, which may be performed at temperatures of around 350° C. to 400° C. that are lower than the temperatures of LPCVD used for forming the first dielectric layer 316. Depending on implementation, the second dielectric layer 334 may have a thickness ranging from tens of nanometers to several hundreds of nanometers. Because of the lower temperatures used in PECVD, the dielectric layer 334 may include hydrogen to a greater degree (e.g., due to less outgassing) than the first dielectric layer 316. Although higher concentrations of hydrogen may be present in the second dielectric layer 334, the risk of hydrogen diffusion into the p-GaN layer 314 (e.g., through the first dielectric layer 316 near the gate region 305B) during subsequent thermal process steps, e.g., a silicide-forming annealing process, is expected to be mitigated in the examples set forth herein because of the lower temperatures used in the silicide-forming annealing process during contact metallization.

FIG. 3C depicts a stage where pluralities of contact apertures 318A, 318B (also referred to as openings or simply apertures) are formed in the source region 305A and the drain region 305D, respectively, for facilitating the formation of multi-column source and drain contacts in subsequent stages. Depending on implementation, individual apertures of the pluralities of apertures 318A, 318B may have suitable form factors and dimensions (e.g., including circular shapes, ovoid shapes, obround shapes, rectangular shapes, square shapes, diamond shapes, etc.). In some implementations, the pluralities of apertures 318A, 318B may be organized in same or different spatial arrangements (e.g., as illustrated in FIGS. 2A-2G). Further, the individual apertures of the pluralities of apertures 318A and 318B may have same or different shapes or sizes in some examples as noted previously.

The apertures 318A/318B may be formed by etching or removing the material from the dielectric layers 334, 316 as well as a portion of heterojunction structure 306, e.g., using a contact aperture mask and a pattern etch process that may comprise one or more etch stages including wet etch and/or dry etch processes in some arrangements. Depending on implementation, contact etch processes may include inductively-coupled plasma (ICP) etch processes, deep reactive ion etching (DRIE) processes, high aspect ratio etch (HARE) processes, etc., without limitation, using suitable chemistries and process recipes. Further, contact etch processes having different etch rates, chemistries, etc. may be implemented for different layers/sublayers of the dielectric layers 316, 334 and/or the heterojunction structure 306.

In some implementations, individual apertures of the pluralities of apertures 318A, 318B may be formed such that the apertures extend into the buffer layer 304 by a suitable depth in order to facilitate contact with the 2 DEG 308 of the GaN device 301. In some examples, the apertures 318A, 318B may extend into the buffer layer 304 by a depth 317 ranging from about 5 nm to about 30 nm, where each individual aperture may have an area corresponding to a mask pattern area of about 0.3 μm by 0.3 μm.

FIG. 3D depicts a stage where an Si layer 319 is formed over the GaN device 301, with the Si layer 319 forming a liner 371 along interior sidewalls of the apertures 318A, 318B. In some arrangements, the Si layer 319 may have a thickness ranging from about 5 nm to about 20 nm or greater. Depending on implementation, the Si layer 319 may be formed using LPCVD or PECVD processes. In some arrangements, precursors such as silane, dichlorosilane (DCS), trichrolosilane (TCS), etc., may be used for deposition, with temperatures ranging from about 450° C. to about 700° C.

In one example implementation, the Si layer 319 may be formed using a low temperature PECVD process using silane (SiH₄) as a precursor supplied at around 12 standard cubic centimeters per minute (sccm) to 16 sccm (depending on the reactor chamber size and deposition rate, for example). Further, an example PECVD Si process may be implemented using pressures ranging from around 0.3 Torr to around 5.0 Torr, at temperatures ranging from about 350° C. to about 600° C. and RF power around 50 watts (W) to 300 W.

FIG. 3E depicts a stage where a refractory metal layer 321 is formed over the Si layer 319 as part of a Si-metal stack for fabricating multi-column contacts according to the examples herein. In some arrangements, the refractory metal layer 321 may include a refractory metal of at least one of titanium (Ti), nickel (Ni), tungsten (W), tantalum (Ta), niobium (Nb), cobalt (Co), platinum (Pt), molybdenum (Mo), rhenium (Re), vanadium (V), zirconium (Zr), hafnium (Hf), ruthenium (Ru), and iridium (Ir), and/or in combination with a nitride of the refractory metal (e.g., Ti/TiN). In an example implementation, the refractory metal layer 321 may be formed using a sputter process, a reactive sputter process, or an ALD process, and may have a thickness ranging from about 10 nm to about 40 nm or greater.

FIG. 3F depicts a stage where a conductive layer 323 is formed over the refractory metal layer 321 using a suitable process, e.g., a sputter process, a reactive sputter process, or an ALD process, to fill the apertures 318A, 318B lined with the Si liner 371 and the refractory metal layer 321. In some arrangements, the conductive layer 323 may comprise a bulk conductive component of a contact column and may comprise a suitable metal such as aluminum, aluminum copper alloy (e.g., including 0.5% Cu), etc. Depending on implementation, the conductive layer 323 may have a thickness of about 30 nm to 200 nm or greater. Further, in some additional and/or alternative arrangements, a metallic barrier layer comprising a refractory metal composition may be formed over the conductive layer 323 as part of a Si-metal stack, e.g., stack 325. In some versions of this example, the Si-metal stack 325 may comprise a Si layer, a Ti layer, and an Al conductive layer.

As previously noted, annealing may be performed at lower temperatures while achieving desirable contact resistance—e.g., at temperatures adequate for forming a metal silicide, at least partially due to the increased perimeter area of the multiple conductive columns of the S/D contacts 322A/322B. Depending on implementation, an annealing process (e.g., a silicide-forming thermal process) may be performed at different stages for forming a metal silicide using at least a portion of the refractory metal layer 321 and at least a portion of the Si layer 319 of the Si-metal stack 325. In some arrangements, the annealing process for forming a metal silicide may be performed prior to depositing the conductive layer 323 in the stage shown in FIG. 3F. Thereafter, the conductive layer 323 may be deposited over the metal silicide. In some arrangements, the annealing process for forming a metal silicide may be performed after depositing the conductive layer 323 in the stage shown in FIG. 3F.

By way of example, FIG. 3G depicts a stage of the semiconductor device 300 after forming a metal silicide 333 based on consuming the entire Si layer 319 and refractory metal layer 321 in an annealing process. The metal silicide 333 may be formed regardless of whether the annealing process was performed before depositing the conductive layer 323 or after depositing the conductive layer 323. In one implementation, the refractory metal layer 321 is a Ti layer and the conductive layer 323 is an Al layer. In one implementation, an annealing process may include rapid thermal annealing (RTA) or furnace annealing at temperatures ranging from about 500° C. to less than 700° C. for about 30 seconds to 5 minutes. In some examples, the metal silicide 333 may have a thickness that is about equal to a total combined thickness of the Si layer 319 and the Ti layer 321. In additional and/or alternative examples, there may be only partial consumption of Si layer 319 and/or Ti layer 321 as previously described. Accordingly, in some examples, there may be a remaining portion of unconsumed Si layer disposed under the metal silicide 333, where the thickness of the unconsumed Si layer may be less than the initial thickness of Si layer 319 as deposited. Likewise, there may be a remaining portion of unconsumed Ti layer extending over or above the metal silicide 333, with the thickness of the unconsumed Ti layer being less than the initial thickness of Ti layer 321 as deposited.

FIG. 3H depicts a stage where a contact metal etch is performed based on appropriate photolithography for defining contact pads 327-1, 327-2 over the filled apertures 318A, 318B. In this manner, multi-column contacts 322A, 322B operable as source and drain electrodes, respectively, may be formed in the source and drain regions 305A, 305D according to the examples herein. As illustrated in FIG. 3H, multi-column contacts 322A, 322B are analogous to the multi-column contact 100B having two conductive columns 150A, 150B shown in FIG. 1B-1. Similar to the contact pad 159 of FIG. 1B-1, contact pads 327-1, 327-2 may comprise the Si-metal stack 325, which may have a thickness depending on the thicknesses of the constituent layers, e.g., conductive layer 323 (as well as a metallic barrier layer where provided) and the underlying metal silicide 333. In additional or alternative arrangements, the multi-column contacts 322A, 322B may have configurations analogous to the multi-column contact 100B shown in FIGS. 1B-2 and 1B-3 where the silicon layer 319 and refractory metal layer 321 are only partially consumed in forming the metal silicide 333.

FIG. 3I-1 depicts a more completely formed semiconductor device 300 including the GaN device 301, where a source terminal 342A, a gate terminal (not shown in FIG. 3I) and a drain terminal 342B are formed through an insulator 350 comprising, e.g., interlevel dielectric (ILD) and/or pre-metal dielectric (PMD) material, for facilitating electrical contact with source electrode 322A, drain electrode 322B and gate electrode 322C, respectively.

FIGS. 3I-2 and 3I-3 depict a more completely formed semiconductor device 300 including additional and/or alternative variations of multi-column contacts according to some examples. As depicted, the examples of FIGS. 3I-2 and 3I-3 are substantially identical to the example shown in FIG. 3I-1. Accordingly, the process flow stages described above with respect to the example of FIG. 3I-1 are also applicable to the examples of FIGS. 3I-2 and 3I-3 except as noted below.

In the example of FIG. 3I-2, the semiconductor device 300 includes multi-column contacts 322A′ and 322B′ formed in respective contact apertures 318A, 318B that do not extend through the barrier layer 310. Accordingly, an example etch process (e.g., similar to the process stage of FIG. 3C) may stop within the barrier layer 310 for forming the contact apertures 318A, 318B. The amount of barrier layer 310 remaining in the contact apertures 318A, 318B may vary depending on implementation. After forming the contact apertures 318A, 318B that extend partially into the barrier layer 310, subsequent process stages of contact metallization and annealing may be performed similar to the stages set forth in FIGS. 3D-3H. For purposes of the present disclosure, multi-column contacts 322A′, 322B′ that partially extend into barrier layer 310 may be referred to as partial-recess multi-column contacts.

In the example of FIG. 3I-3, the semiconductor device 300 includes multi-column contacts 322A″ and 322B″ formed in respective contact apertures 318A, 318B that terminate on a top surface of the barrier layer 310 in an etch process (e.g., in a process stage similar to FIG. 3C). After forming the contact apertures 318A, 318B that do not extend into the barrier layer 310, subsequent process stages of contact metallization and annealing may be performed similar to the stages set forth in FIGS. 3D-3H. Accordingly, the multi-column contacts 322A″ and 322B″ do not extend into the barrier layer 310. For purposes of the present disclosure, multi-column contacts 322A″, 322B″ that do not extend into the barrier layer 310 may be referred to as no-recess multi-column contacts.

Although the multi-column contacts 322A′/322B′ and 322A″/322B″ do not physically contact the 2 DEG 308 in the examples of FIGS. 3I-2 and 3I-3, electrical ohmic contact formation may be facilitated by reaction between the barrier layer 310 and the Si-metal stack of the conductive columns during silicide-forming thermal processing. For example, reaction between the barrier layer 310 and the Si-metal stack may be facilitated by mechanisms such as nitrogen vacancy formation, barrier tunneling, metal spiking, etc.

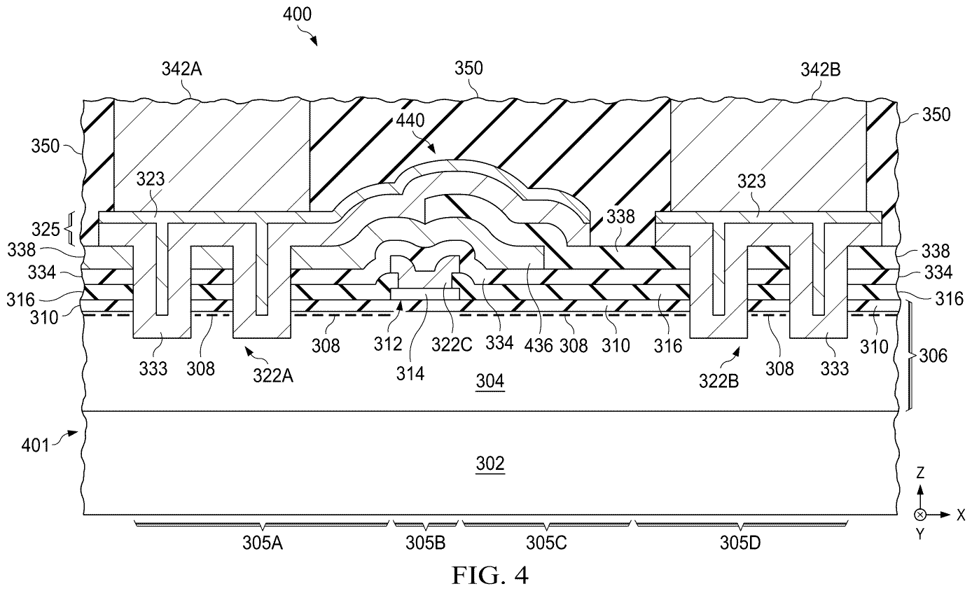

FIG. 4 depicts a cross-sectional view of a semiconductor device 400 including a GaN device 401 where a field plate structure may be associated with a multi-column contact of the GaN device 401 in some examples of the present disclosure. As illustrated, the GaN device 401 is substantially similar to the GaN device 301 except for a first field plate (FP1) 436, a second FP (FP2) 440 and a dielectric layer 338 at least partially disposed therebetween, where multi-column source and drain contacts 322A, 322B of the GaN device 401 may be fabricated using a gate first flow similar to the flow described above. Accordingly, the description of the gate first flow set forth above with respect to FIGS. 3A-3H is also applicable with respect to the formation of the semiconductor device 400 except as otherwise noted herein. Depending on implementation, the formation of the semiconductor device 400 may include a self-aligned source contact process or a non-self-aligned source contact process, which may be used for forming multiple conductive columns of a source contact in some examples. In some arrangements, FP1 436 may be formed from an Al-based FP metal layer formed over the dielectric layer 334 using a deposition process, e.g., a physical vapor deposition (PVD) process, where the FP metal layer may include an adhesion layer (not explicitly shown in FIG. 4) of TiN, titanium-tungsten (TiW), etc., contacting the dielectric layer 334. In some arrangements, FP1 436 may have a thickness of about 30 nm to 500 nm.

In an example self-aligned source contact process, FP1 436 may be provided as a hard mask for contact aperture formation. Accordingly, FP1 436 may fully extend to and contact a conductive column of the multi-column source electrode 322A nearest to the gate region 305B in some arrangements, e.g., as illustrated in FIG. 4. In a non-self-aligned source contact process, FP1 436 may extend only partially over a portion of the source region 305A, thus lacking a direct contact with the multi-column source contact 322A.

In some examples, a dielectric layer 338 is formed over at least a portion of FP1 436 as illustrated in FIG. 4. As depicted, the dielectric layer 338, which may be referred to as a third dielectric layer in some examples, may be patterned to extend across the drain access region 305C while partially overlying FP1 436 in the gate region 305B. Similar to the second dielectric layer 334, the third dielectric layer 338 may be formed using PECVD and may comprise SiN or similar material including hydrogen. Although the hydrogen in the third dielectric layer 338 could be susceptible to diffusion at high temperatures, that risk may be advantageously mitigated in the disclosed examples because of low-temperature contact annealing facilitated by the multi-column contact design used in the fabrication of the source and drain contacts 322A, 322B as previously noted.

A contact metallization process including Si-metal stack formation and annealing may be performed similar to the stages set forth in FIGS. 3C-3H, except that in the example of FIG. 4, a second FP, e.g., FP2 440, coupled to the multi-column source contact 322A may be formed during contact patterning. In one arrangement, FP2 440 may extend at least partially over the third dielectric layer 338 as shown in FIG. 4. Similar to the example of FIG. 3I, each conductive column of the multi-column source/drain contacts 322A/322B includes the metal silicide 333 formed in a suitable annealing process as previously described. Accordingly, the conductive columns of the multi-column source/drain contacts 322A/322B each contain metal silicide sidewall portions contacting the buffer layer 304 including the 2 DEG 308. Further, the semiconductor device 400 of FIG. 4 including the GaN device 401 is provided with the source and drain terminals 342A, 342B similar to the arrangement shown in FIG. 3I. Additional details relating to a self-aligned contact process flow that may be combined with some examples of a multi-column contact design as set forth herein may be found in Application No. Ser. No. 18/189,870, filed on Mar. 24, 2023, which is incorporated by reference herein in its entirety for all purposes.

Although the examples of the present disclosure particularly describe Al-based Si-metal stacks for forming multi-column contacts, other liner materials and/or metals may be used for forming conductive columns in additional and/or alternative implementations. Furthermore, whereas the examples are set forth in detail in the context of forming multi-column contacts after the formation of a gate stack (e.g., in a gate first process flow), the teachings of the present disclosure are not limited thereto. Accordingly, multi-column contacts operable as source/drain contacts in a GaN device, e.g., source/drain contacts 322A/322B, may also be fabricated in a gate last process flow according to some additional and/or alternative examples where the multi-column contacts are formed before a gate stack including a gate electrode is formed.

In some implementations, hydrogen-containing dielectric layers (which surround or overlie the gate stack including p-GaN layer) may be formed in a gate last flow after the source and drain electrodes are already formed. Accordingly, the risk of hydrogen diffusion and concomitant dopant deactivation due to high temperature contact annealing may be minimal in such a flow, thus diminishing the need for a multi-column contact design to overcome that issue. Nevertheless, a multi-column contact design coupled with Si-liner process may be included in a gate last flow according to some additional and/or alternative examples where the benefits of lower contact resistance may still be realized. Further, because of the colonnade-like arrangement of a plurality of conductive columns formed in the heterojunction structure of a device, the conductive columns of a drain contact at one end facing the gate stack are operable to shield the interior conductive columns from charge trapping events near the drain contact. Accordingly, better device reliability (e.g., R_{DSON} stability) under high voltage/current conditions may be obtained in “gate last” GaN devices also. Additional details relating to an example gate last process flow that may be combined with some examples of a multi-column contact design as set forth herein may be found in application Ser. No. 18/788,650, filed on Jul. 30, 2024, which is incorporated by reference herein in its entirety for all purposes.

Furthermore, some multi-column contact designs of the present disclosure may allow the formation of drain contacts that increase effective gate-to-drain length (Lgd) in a GaN device without increasing the actual lateral spacing between a gate and a drain in the device. For example, a staggered column design such as the design 200H-1 (shown in FIG. 2H-1), increases effective Lgd because of alternating columns that are spaced further apart from the gate. Devices with longer Lgd may be able to withstand higher voltages and may therefore advantageously support higher voltage applications with greater reliability.

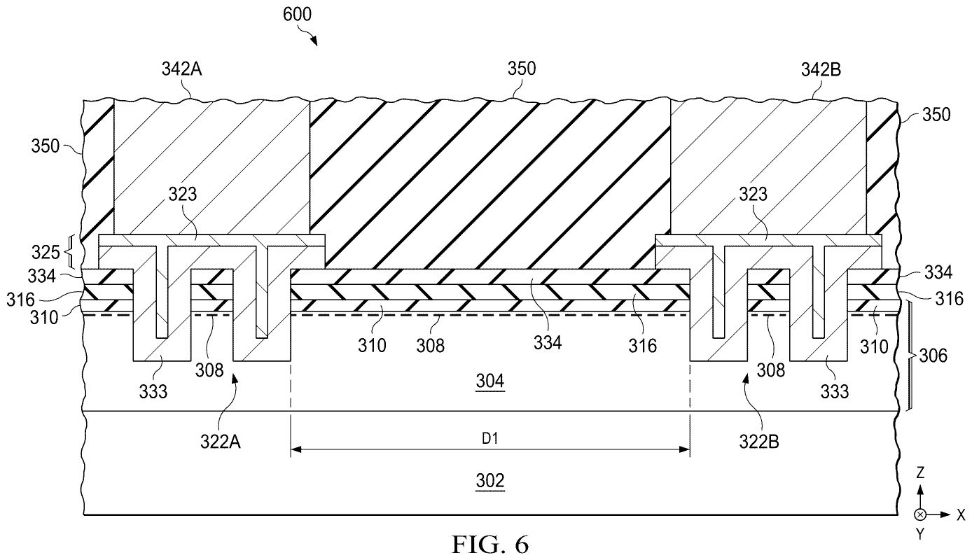

In further variations, an example multi-column contact design of the present disclosure may be implemented in the fabrication of GaN resistors using similar process stages as described above. In such implementations, the formation of a gate stack (e.g., including a p-GaN layer for EMODE GaN transistor) over the barrier layer 310 may be omitted. FIG. 6 depicts a GaN resistor 600 including multi-column contacts 322A, 322B according to an example of the present disclosure. As illustrated, a continuous 2 DEG 308 is formed in the heterojunction structure 306 because of lack of a p-GaN layer overlying the barrier layer 310. Multi-column contacts 322A, 322B including Si-metal stacks are formed similar to the structures shown in FIGS. 1B-1 to 1B-3 described above. In some examples, the multi-column contacts 322A, 322B may be laterally spaced apart by a distance D1 depending on a desired resistance and/or the sizing of the GaN resistor 600. The 2 DEG extending between the multi-column contacts 322A, 322B is therefore operable as a resistor body according to the examples herein. Further, the multi-column contacts 322A, 322B are operable as resistor heads coupled to respective terminals 342A, 342B of the GaN resistor 600.

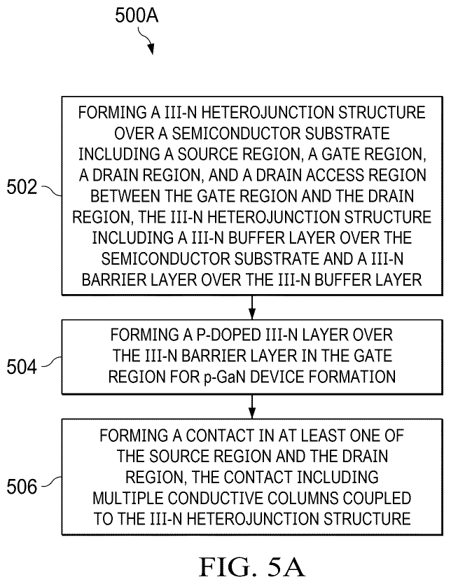

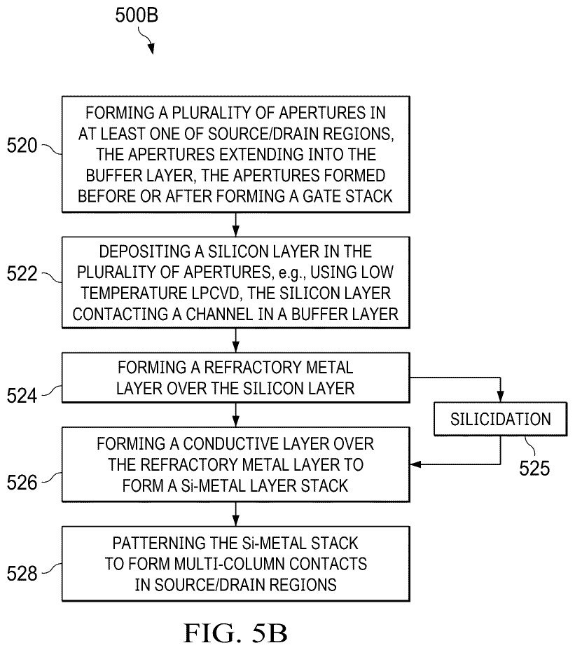

FIGS. 5A and 5B are flowcharts of methods of fabricating a semiconductor device including multi-column contacts according to some examples of the present disclosure. Method 500A shown in FIG. 5A may commence with forming a III-N heterojunction structure over a semiconductor substrate, where the III-N heterojunction structure may include a III-N buffer layer over the semiconductor substrate and a III-N barrier layer over the buffer layer. At block 504, a p-doped III-N layer is formed over the III-N barrier layer in the gate region for facilitating p-GaN functionality. In some examples, the steps set forth at blocks 502 and 504 may relate to certain aspects of FIG. 3A as described above. At block 506, a contact is formed in the source region and/or the drain region, where the contact includes multiple conductive columns coupled to at least a portion of the III-N heterojunction structure, which may relate to some aspects of FIGS. 3C-3G as described above.

Method 500B shown in FIG. 5B illustrates additional steps that may be employed for performing certain aspects relating to block 506 of FIG. 5A. At block 520, a plurality of apertures may be formed in the source region and/or drain region of a GaN device. In some arrangements, the plurality of apertures may be formed before or after forming a gate stack of the GaN device. In some arrangements, the plurality of apertures extend to at least a portion of the III-N heterojunction structure, e.g., a III-N buffer layer operable to support a conducive channel. Further, the aperture formation may include a self-aligned contact process or a non-self-aligned contact process as previously noted.

At block 522, a silicon layer may be deposited in the plurality of apertures, e.g., using a low temperature deposition process such as PECVD, where the silicon layer forms a liner in the contact apertures operable to contact a channel of the GaN device (e.g., a 2-dimensional electron gas (2 DEG) or a 2D hole gas (2DHG)). In some examples, these steps set forth at block 522 may relate to aspects of FIG. 3D. At block 524, a refractory metal layer may be deposited over the silicon layer, which may relate to some aspects of FIG. 3E. In some arrangements, the rate of refractory metal layer deposition may be controlled based on factors such as the number of apertures, aperture form factor (e.g., depth and width of individual apertures), spatial configuration of the apertures, etc., in order to facilitate better process control. At block 526, a conductive layer, e.g., comprising aluminum, may be formed over the refractory metal layer to form a Si-metal stack. In some examples, the steps set forth at block 526 may relate to aspects of FIG. 3F. At block 525, a silicide-forming annealing process at low temperatures (e.g., ranging from about 500° C. to less than 700° C.) may be performed before depositing the conductive layer or after depositing the conductive layer. Thereafter, the Si-metal stack is patterned to form multi-column contacts in the source and/or drain regions, respectively (block 528). In some examples, the steps set forth at block 528 may relate to aspects of FIG. 3H.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately or directly over the other component, or that one component is immediately or directly under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A semiconductor device, comprising:
a semiconductor substrate including a source region, a gate region, a drain region, and a drain access region between the gate region and the drain region;
a III-N heterojunction structure over the semiconductor substrate, the III-N heterojunction structure including a buffer layer over the semiconductor substrate and a barrier layer over the buffer layer; and
a contact in at least one of the source region and the drain region, the contact including multiple conductive columns coupled to the III-N heterojunction structure.

2. The semiconductor device of claim 1, wherein the multiple conductive columns extend to or into the buffer layer.

3. The semiconductor device of claim 2, wherein the multiple conductive columns are coupled to a channel in the buffer layer.

4. The semiconductor device of claim 1, further comprising:
a p-doped III-N layer over the barrier layer in the gate region.

5. The semiconductor device of claim 1, wherein the multiple conductive columns are organized in an (N×M) array.

6. The semiconductor device of claim 1, wherein each conductive column of the contact has a same cross-sectional area.

7. The semiconductor device of claim 1, wherein at least one conductive column of the contact has a different cross-sectional area than other conductive columns of the contact.

8. The semiconductor device of claim 1, wherein each conductive column of the contact includes:
a metal silicide; and
a conductive layer over the metal silicide.

9. The semiconductor device of claim 8, wherein the metal silicide has a thickness ranging from about 5 nanometers (nm) to about 40 nm.

10. The semiconductor device of claim 8, wherein the metal silicide includes at least one of titanium, tungsten, tantalum, niobium, cobalt, platinum, molybdenum, rhenium, vanadium, zirconium, hafnium, ruthenium, and iridium.

11. The semiconductor device of claim 8, further comprising:
a silicon layer wherein the metal silicide is on the silicon layer.

12. The semiconductor device of claim 11, wherein the silicon layer has a thickness of less than 5 nm.

13. The semiconductor device of claim 8, further comprising:
a refractory metal layer, wherein the refractory metal layer is on the metal silicide.

14. The semiconductor device of claim 13, wherein the refractory metal layer has a thickness of less than 10 nm.

15. The semiconductor device of claim 8, wherein the conductive layer comprises aluminum.

16. A method, comprising:
forming a III-N heterojunction structure over a semiconductor substrate including a source region, a gate region, a drain region, and a drain access region between the gate region and the drain region, the III-N heterojunction structure including a buffer layer over the semiconductor substrate and a barrier layer over the buffer layer; and
forming a contact in at least one of the source region and the drain region, the contact including multiple conductive columns coupled to the III-N heterojunction structure.

17. The method of claim 16, further comprising:
extending the multiple conductive columns to or into the buffer layer.

18. The method of claim 16, further comprising:
forming a p-doped III-N layer over the barrier layer in the gate region.

19. The method of claim 16, wherein the contact is formed before forming a gate stack in the gate region.

20. The method of claim 16, wherein the contact is formed after forming a gate stack in the gate region.

21. The method of claim 16, wherein forming the contact comprises:
forming a plurality of apertures in the at least one of the source region and the drain region, individual apertures of the plurality of apertures extending to or into the buffer layer;
depositing a silicon layer in the plurality of apertures, the silicon layer contacting the buffer layer;
depositing a refractory metal layer over the silicon layer; and
depositing a conductive layer over the refractory metal layer.

22. The method of claim 21, wherein the silicon layer is formed by a plasma enhanced chemical vapor deposition (PECVD) process at a temperature ranging from about 350° C. to about 600° C.

23. The method of claim 22, wherein the PECVD process uses a silane (SiH₄) gas precursor supplied at around 12 standard cubic centimeters per minute (sccm) to 16 sccm, the PECVD process having a pressure ranging from about 0.3 Torr to about 5.0 Torr and an RF power ranging from about 50 W to about 300 W.

24. The method of claim 21, wherein the refractory metal layer includes at least one of titanium, tungsten, tantalum, niobium, cobalt, platinum, molybdenum, rhenium, vanadium, zirconium, hafnium, ruthenium, and iridium.

25. The method of claim 21, wherein the conductive layer comprises aluminum.

26. The method of claim 21, further comprising:
forming a metal silicide based on the silicon layer and the refractory metal layer.

27. The method of claim 26, wherein forming the metal silicide includes:
performing annealing at a temperature ranging from about 500° C. to less than 700° C. for about a time period of 30 seconds to 5 minutes.

28. The method of claim 26, wherein forming the metal silicide is done prior to depositing the conductive layer.

29. The method of claim 26, wherein forming the metal silicide is done after depositing the conductive layer.
